(19) United States
(12) Patent Application Publication
(10) Pub. No.: US 2025/0279734 A1
(43) Pub. Date: Sep. 4, 2025

(54) ENERGY RECOVERY CIRCUIT AND POWER SUPPLY SYSTEM INCLUDING THE SAME

(71) Applicant: LG Display Co., Ltd., Seoul (KR)

(72) Inventors: Min Ho SOHN, Paju-si (KR); Seung Hyeon KIM, Paju-si (KR)

(73) Assignee: LG Display Co., Ltd., Seoul (KR)

(21) Appl. No.: 19/039,158

(22) Filed: Jan. 28, 2025

(30) Foreign Application Priority Data
Feb. 29, 2024 (KR) 10-2024-0029767

(51) Int. Cl. H02N 2/18; H02J 7/00

(52) U.S. Cl. CPC H02N 2/186; H02J 7/007182

(57) ABSTRACT

The present disclosure may provide an energy recovery circuit, which includes a summing circuit that amplifies or sums electricity output from one or more vibration generators in response to vibration of a panel member, a rectifying circuit that rectifies an output signal of the summing circuit, and a charging circuit that charges electricity output from the rectifying circuit.

### CROSS-REFERENCE TO RELATED APPLICATION

This application claims priority to and the benefit of Korean Patent Application No. 10-2024-0029767, filed Feb. 29, 2024, the disclosure of which is incorporated herein by reference in its entirety.

### BACKGROUND

### Technical Field

The present disclosure relates to an energy recovery circuit connected to a vibration device and a power supply system including the same.

### Description of the Related Art

A vibration device is a device that converts an electric signal into vibration of an object or converts vibration of an object into electrical energy. Vibration devices are widely used in various industrial fields including user interfaces using haptic technology, speakers that output sound, vibration sensors, and piezoelectric sensors.

### BRIEF SUMMARY

In some implementations, the vibration energy of an object is recovered and utilized as driving power for a vibration device or as driving power for other devices, and the power consumption of various systems connected to the vibration device may be improved and waste of resources may be reduced.

The present disclosure provides an energy recovery circuit capable of recovering vibration energy and a power supply system including the same.

The technical features of this disclosure are not limited to those mentioned above, and other features not mentioned will be clearly understood by those skilled in the art from the following description.

An energy recovery circuit according to one embodiment of the present disclosure may include a summing circuit configured to amplify or sum electricity output from one or more vibration generators in response to vibration of a panel member; a rectifying circuit configured to rectify an output signal of the summing circuit; and a charging circuit configured to charge with electricity output from the rectifying circuit.

An energy recovery circuit according to another embodiment of the present disclosure may include a summing and rectification circuit configured to amplify or sum and rectify electricity output from a plurality of vibration generators in response to vibration of a panel member; and a charging circuit configured to charge with a DC voltage output from the summing and rectification circuit.

A power supply system according to another embodiment of the present disclosure may include a panel member on which a plurality of vibration generators are arranged; a control part that is configured to control, among the vibration generators arranged on the panel member, one or more first vibration generators in vibration mode and control one or more second vibration generators in energy harvest mode; a plurality of driving parts that are configured to vibrate the first vibration generators under the control of the control part and receive electricity output from the second vibration generators in response to vibration of the panel member; and an energy recovery circuit that is configured to charge with the electricity output from the second vibration generators through the driving parts.

According to an embodiment of the present disclosure, vibration energy may be recovered without power consumption or heat generation by converting vibration in a panel member into an electric signal, and it may be used as driving power for vibration generators or other electronic devices, thereby improving the lifespan of the system.

According to an embodiment of the present disclosure, vibration of the panel member may be utilized as system driving power, thereby contributing to reducing resource waste and improving the environment.

The effects of this disclosure are not limited to those mentioned above, and other effects not mentioned will be clearly understood by those skilled in the art from the detailed description, the drawings, and the claims.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a block diagram illustrating a power supply system according to an embodiment of the present disclosure;

FIGS. 2A and 2B are a top view showing an example of a panel member according to an embodiment of the present disclosure;

FIG. 3 is a flowchart illustrating a mode-specific control method of the power supply system according to an embodiment of the present disclosure;

FIG. 4 is a diagram illustrating a configuration of the power supply system according to an embodiment of the present disclosure;

FIG. 5 is a diagram illustrating a control part and plural driving parts according to an embodiment of the present disclosure;

FIGS. 6A and 6B are diagrams showing an example of a method for controlling the driving parts illustrated in FIG. 5;

FIG. 7 is a diagram showing a panel member sample to which an experiment is applied to verify the energy recovery effect of the power supply system according to an embodiment of the present disclosure;

FIGS. 8A to 8D are diagrams showing characteristics of the input signal and output signal of a first vibration generators driven in vibration mode;

FIG. 9 is a diagram showing the waveform of an electric signal output by the piezoelectric effect from second vibration generators in the sample illustrated in FIG. 7;

FIG. 10 is a circuit diagram showing a summing and rectification integrated circuit according to an embodiment of the present disclosure;

FIG. 11 is a circuit diagram showing a summing and selection circuit according to an embodiment of the present disclosure;

FIG. 12 is a diagram showing a vibration generator according to an embodiment of the present disclosure;

FIG. 13 is a cross-sectional view showing the cross-sectional structure of the vibration generator taken along line I-I′ in FIG. 12;

FIG. 14 is a cross-sectional view showing the cross-sectional structure of the vibration generator taken along line II-II′ in FIG. 12;

FIG. 15 is a diagram showing a vibration medium layer according to an embodiment of the present disclosure;

FIG. 16 is a diagram showing a vibration medium layer according to another embodiment of the present disclosure; and

FIG. 17 is a diagram showing a vibration generator according to another embodiment of the present disclosure.

### DETAILED DESCRIPTION

The advantages and features of the present disclosure and methods for accomplishing the same will be more clearly understood from embodiments described below with reference to the accompanying drawings.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the present specification. Further, in describing the present disclosure, detailed descriptions of known related technologies may be omitted to avoid unnecessarily obscuring the subject matter of the present disclosure.

The terms such as “comprising,” “including,” “having,” and “containing” used herein are generally intended to allow other components to be added unless the terms are used with the term “only.” Any references to singular may include plural unless expressly stated otherwise.

Components are interpreted to include an ordinary error range even if not expressly stated.

When a positional or interconnected relationship is described between two components, such as “on top of,” “above,” “below,” “next to,” “connect or couple with,” “crossing,” “intersecting,” or the like, one or more other components may be interposed between them, unless “immediately” or “directly” is used.

When a temporal antecedent relationship is described, such as “after,” “following,” “next to,” “before,” or the like, it may not be continuous on a time base unless “immediately” or “directly” is used.

In description of the embodiment, the terms “first,” “second,” and the like may be used to distinguish elements from each other, but the functions or structures of the components are not limited by ordinal numbers or component names in front of the components. Accordingly, the first element referred to herein may also be the second element within the technical ideas of the present disclosure.

Like reference numerals refer to like elements throughout the specification.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

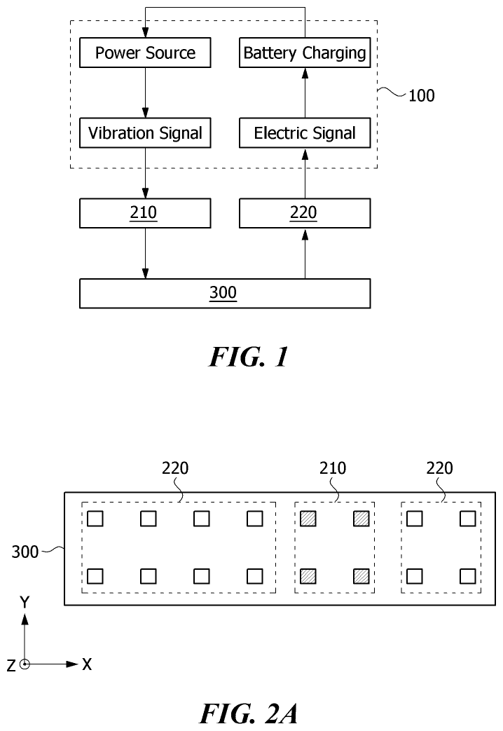

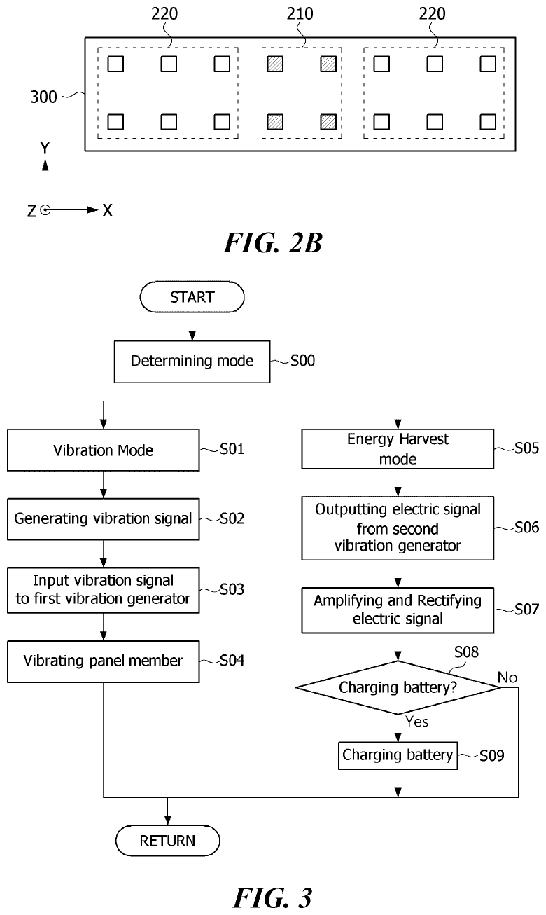

FIG. 1 is a block diagram illustrating a power supply system according to an embodiment of the present disclosure. FIGS. 2A and 2B are a top view showing an example of a panel member.

With reference to FIGS. 1 to 2B, the power supply system 100 may be electrically connected to plural vibration generating parts 210 and 220. The vibration generating parts 210 and 220 may be disposed on a vibration propagation medium 300. The vibration propagation medium 300 may be a vibration plate, a panel member, or a vibration member, but embodiments of the present disclosure are not limited thereto.

The power supply system 100 may individually control the vibration generating parts 210 and 220 to operate in vibration mode (driving mode) or energy harvest mode. The power supply system 100 may include a driving part, an energy recovery circuit, a charging circuit, or the like, but embodiments of the present disclosure are not limited thereto.

The power supply system 100 may generate and amplify a vibration signal when vibration occurs, for example, when a touch input is detected or an audio signal is input, and apply it to at least one of the vibration generating parts 210 and 220 selected for operation in vibration mode. The vibration signal input to the vibration generating parts 210 and 220 in vibration mode may be, but not limited to, an electric signal having a vibration frequency such as a haptic signal or an audio signal. When a touch input from a user's finger or pen is detected, the first vibration generating parts 210 present at the touch input position as shown in FIGS. 2A and 2B may operate in vibration mode to generate vibration. As the touch input position changes, the operation mode of each of the first vibration generating parts 210 and the second vibration generating parts 220 may change. For example, when the touch input moves to the left, as shown in FIG. 2A and FIG. 2B, some of the second vibration generating parts 220 may be controlled along the touch input position to function as the first vibration generating parts 210 operating in vibration mode.

The power supply system 100 may amplify (or sum) and rectify an electric signal output from the vibration generating parts 210 and 220 selected for operation in energy harvest mode and then supply it to a charging circuit to charge a battery of the charging circuit. The charging circuit may include a circuit for remaining battery capacity measurement (or detection). By using the power charged in the battery, the power supply system 100 may generate a vibration signal to drive the vibration generating parts 210 and 220, or output an electric signal to be used as a power source for another electric device.

Each of the vibration generating parts 210 and 220 may operate in vibration mode or energy harvest mode according to the control of the power supply system 100. Each of the vibration generating parts 210 and 220 may generate vibration in vibration mode according to a vibration signal applied from the power supply system 100. In vibration mode, the vibration generating parts 210 and 220 may generate vibration according to the converse piezoelectric effect. In energy harvest mode, each of the vibration generating parts 210 and 220 may convert vibrations transmitted from the vibration propagation medium 300 into an electric signal and supply it to the power supply system 100 without generating vibrations. The vibration generating parts 210 and 220 selected for operation in energy harvest mode may output electricity in a non-driving state where no vibration signal is input in response to the vibration of the vibration propagation medium 300, so that power may be generated without power consumption or heat generation. In energy harvest mode, the vibration generating parts 210 and 220 may output an electric signal obtained from vibrations transferred through the vibration propagation medium 300 according to the piezoelectric effect.

In the following description, the first vibration generating part 210 is described as a vibration generator that generates vibration in vibration mode, and the second vibration generating part 220 is described as a vibration generator that converts vibration into an electric signal in energy harvest mode. However, embodiments of the present disclosure are not limited thereto.

The vibration generating parts 210 and 220 may be a vibration element, a vibration generation element, a vibration film, a vibration generation film, a vibrator, a vibration generator, an active vibrator, an active vibration generator, an actuator, an exciter, a film actuator, a film exciter, an ultrasonic actuator, or an active vibration member. However, embodiments of the present disclosure are not limited thereto.

The vibration propagation medium 300 may be a medium or material capable of propagating vibration such as, but not limited to, glass, metal, or plastic. Hereinafter, the vibration propagation medium 300 is referred to as “panel member.” The panel member 300 may be, but not limited to, a rectangular panel having a length in the X-axis direction (or, first direction), a width in the Y-axis direction (or, second direction), and a thickness in the Z-axis direction (or, third direction). For example, at least a portion of the panel member 300 may include a curved outer edge, an acute/obtuse corner, or the like, but embodiments of the present disclosure are not limited thereto. The panel member 300 on which the vibration generating parts 210 and 220 are arranged may be a panel member for used in, but not limited to, a touchscreen, a touch pad, a haptic device, or a sound output device. At least a portion of the panel member 300 may be overlapped or combined with the display panel of a display device.

FIG. 3 is a flowchart illustrating a mode-specific control method of the power supply system.

With reference to FIG. 3, the power supply system 100 may determine the operation mode of the vibration generating parts 210 and 220 (S00).

The power supply system 100 may determine a first vibration generating part 210 for operation in vibration mode (S01) and determine a second vibration generating part 220 for operation in energy harvest mode (S05). The power supply system 100 may control the first vibration generating part 210 to operate in vibration mode and control the second vibration generating part 220 to operate in energy harvest mode at the same time. When a touch input is detected, the vibration generator at the touch input position among the vibration generating parts 210 and 220 may be determined as the first vibration generating part 210 based on the touch input position. The power supply system 100 may generate a vibration signal by setting the frequency, phase, voltage value or the like of the vibration signal to be input to the first vibration generating part 210 (S02). The power supply system 100 may amplify the vibration signal and apply it to the first vibration generating part 210 (S03). The first vibration generating part 210 may vibrate according to the vibration signal from the power supply system 100, and the panel member 300 may vibrate in association with the vibration of the first vibration generating part 210 (S04).

The second vibration generating part 220 may output an electric signal according to the vibration transferred through the panel member 300 (S06). The power supply system 100 may output or sample an electric signal of an AC waveform by setting a sampling frequency and a reference voltage for the electric signal of an AC waveform received from the second vibration generating part 220 (S06). The power supply system 100 may amplify the sampled electric signal, rectify it, and convert it into a DC voltage (S07). The power supply system 100 may charge the battery of the charging circuit with the DC voltage obtained from the second vibration generating part 220 based on the result of measuring the remaining battery capacity (S08 and S09). If the battery is fully charged, the power supply system 100 may skip charging the battery.

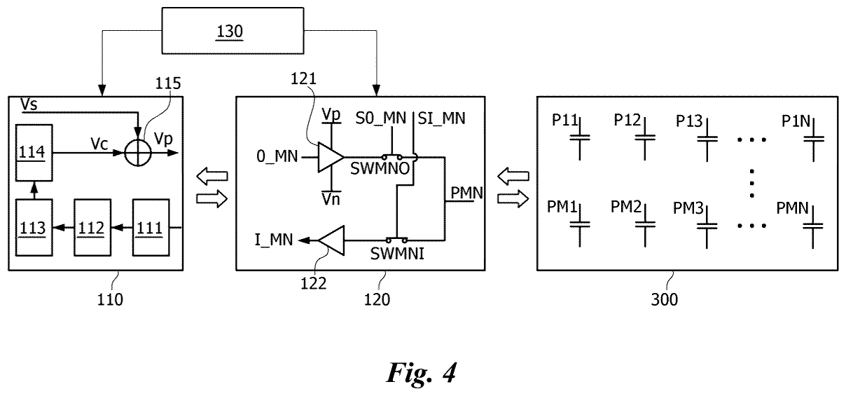

FIG. 4 is a diagram illustrating a configuration of the power supply system.

With reference to FIG. 4, the power supply system 100 may include an energy recovery circuit 110, a driving part 120, and a control part 130, but embodiments of the present disclosure are not limited thereto.

The control part 130 may control the driving part 120 and the energy recovery circuit 110 by generating a control signal and power required for the mode specific operation of the driving part 120 and the energy recovery circuit 110. Under control of the control part 130, a first voltage Vs may be output from power input from the outside and a vibration signal O_MN and switch control signals SO_MN and SI_MN may be output.

The driving part 120 may include a vibration driver 121, an amplifier 122, a first switch element SWMNO, and a second switch element SWMNI. In vibration mode, the vibration driver 121 may amplify the vibration signal O_MN input from the control part 130 and supply it to the first switch element SWMNO. In FIG. 4, the driving voltage Vp and the ground voltage Vn connected to the vibration driver 121 may be the driving voltage and the ground voltage of the amplifier, but embodiments of the present disclosure are not limited thereto.

The driving part 120 may be electrically connected individually or in groups to M*N (M and N are positive integers) vibration generators P11 to PMN arranged on the panel member 300 to individually supply a vibration signal O_MN to the vibration generators P11 to PMN.

The first switch element SWMNO may be turned on in response to the first switch control signal SO_MN. When the first switch element SWMNO is turned on, the vibration signal O_MN may be supplied to those vibration generators P11˜PMN selected for operation in vibration mode. The vibration signal O_MN may include a positive polarity signal and a negative polarity signal (or ground voltage).

The second switch element SWMNI may be turned on in response to the second switch control signal SI_MN. When the second switch element SWMNI is turned on, an electric signal I_MN output from one or more vibration generators P11 to PMN selected for operation in energy harvest mode may be input to the amplifier 122. The electric signal I_MN output from the vibration generators P11˜PMN operating in energy harvest mode may be an electric signal of an AC waveform, but embodiments of the present disclosure are not limited thereto. The second switch element SWMNI may be connected to a sampling circuit to sample an electric signal of an AC waveform.

The amplifier 122 may amplify the electric signal input through the second switch element SWMNI and supply it to the energy recovery circuit 110.

The energy recovery circuit 110 may include a first summing circuit 111, a rectifying circuit 112, a charging circuit 113, a voltage stabilizing circuit 114, and a second summing circuit 115, but embodiments of the present disclosure are not limited thereto.

The first summing circuit 111 may amplify an electric signal received from those vibration generators P11 to PMN operating in energy harvest mode through the amplifier 122. The first summing circuit 111 may amplify the electric signal by summing electric signals of an AC waveform received through the amplifier 122 from the plural vibration generators P11 to PMN.

The rectifying circuit 112 may rectify an AC waveform electric signal input from the vibration generators controlled for operation in energy harvest mode to convert it into a DC signal. The charging circuit 113 may charge the battery with the DC voltage input through the rectifying circuit 112.

The voltage stabilizing circuit 114 may adjust the voltage charged in the battery of the charging circuit 113 to stabilize it to a desired voltage level and output a second voltage Vc. The voltage stabilizing circuit 114 may output the second voltage Vc output through a regulator, without being limited thereto.

The second summing circuit 115 may output the first voltage Vs or output the result of adding the second voltage Vc to the first voltage Vs according to the control of the control part 130. The voltage Vp output from the second summing circuit 115 may be applied to the vibration driver 121 as an amplifier driving voltage Vp of the vibration driver 121 that amplifies the vibration signal.

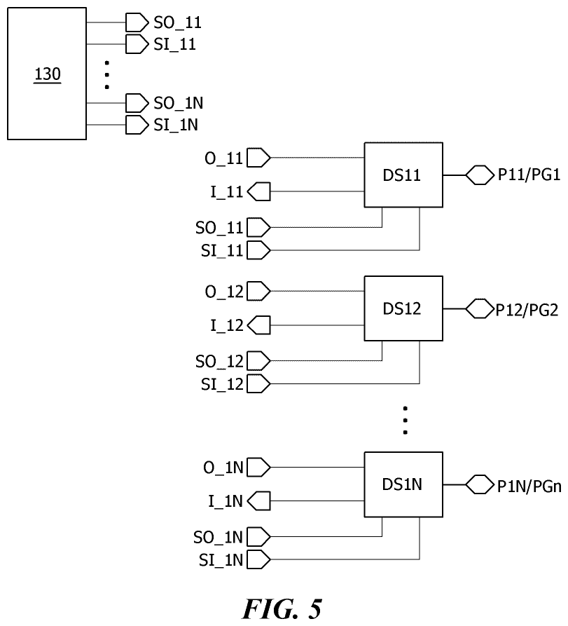

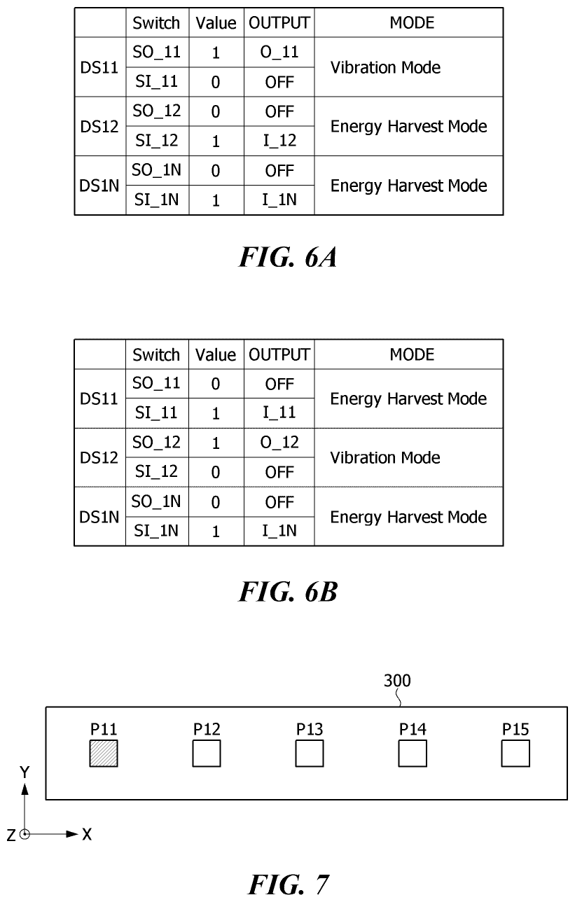

FIG. 5 is a diagram illustrating a control part and plural driving parts. FIGS. 6A and 6B are diagrams showing an example of a method for controlling the driving parts illustrated in FIG. 5.

With reference to FIGS. 5 to 6B, the power supply system 100 may include a plurality of driving parts DS11 to DS1N.

The driving parts DS11 to DS1N may be connected respectively to the vibration generators P11 to PIN, and each thereof may drive a single vibration generator in vibration mode or energy harvest mode under the control of the control part 130. In another embodiment, the driving parts DS11 to DS1N may be connected to n (n is a positive integer greater than or equal to 2) vibration generators and may control the vibration generators in groups. For example, the first driving part DS11 may be connected to two to four vibration generators belonging to the first vibration generator group PG1 and may drive these vibration generators in vibration mode or energy harvest mode under the control of the control part 130. In FIG. 5, reference symbols “P11 to PIN” indicate individual vibration generators, and “PG1 to PGn” indicate vibration generator groups each including multiple vibration generators.

The control part 130 may output switch control signals SO_11 to SO_IN and SI_11 to SI_IN for independently controlling the driving parts DS11 to DS1N. As shown in FIGS. 6A and 6B, the first switch control signals SO_11 to SO_IN may be generated as an active logic value, for example, 1 (or High), in vibration mode, while being generated as an inactive logic value, for example, 0 (or Low), in energy harvest mode. As shown in FIGS. 6A and 6B, the second switch control signals SI_11 to SI_IN may be generated as an active logic value, for example, 1 (or High), in energy harvest mode, while being generated as an inactive logic value, for example, 0 (or Low), in vibration mode.

The first driving part DS11 may receive first and second switch control signals SO_11 and SI_11 and a vibration signal O_11 from the control part 130, and supply an electric signal I_11 obtained from the vibration of the panel member 300 to the energy recovery circuit 110. The N^{th} driving part DS1N may receive first and second switch control signals SO_IN and SI_IN and a vibration signal O_IN from the control part 130, and supply an electric signal I_IN obtained from the vibration of the panel member 300 to the energy recovery circuit 110.

As shown in FIGS. 6A and 6B, the control part 130 may control one or more of the driving parts DS11 to DS1N for operation in vibration mode, while simultaneously controlling the other driving parts for operation in energy harvest mode.

In the example of FIG. 6A, the first driving part DS11 may drive the corresponding vibration generator P11 or the vibration generators of the corresponding vibration generator group PG1 in vibration mode in response to the switch control signals SO_11 and SI_11. At this time, other driving parts DS12 and DS1N may drive the corresponding vibration generators P12 and PIN or vibration generators of the corresponding vibration generator groups PG2 and PGn in energy harvest mode in response to the switch control signals SO_12, SO_IN, SI_12 and SI_IN.

In the example of FIG. 6B, the second driving part DS12 may drive the corresponding vibration generator P12 or the vibration generators of the corresponding vibration generator group PG2 in vibration mode in response to the switch control signals SO_12 and SI_12. At this time, other driving parts DS11 and DS1N may drive the corresponding vibration generators P11 and PIN or vibration generators of the corresponding vibration generator groups PG1 and PGn in energy harvest mode in response to the switch control signals SO_11, SO_IN, SI_11 and SI_IN.

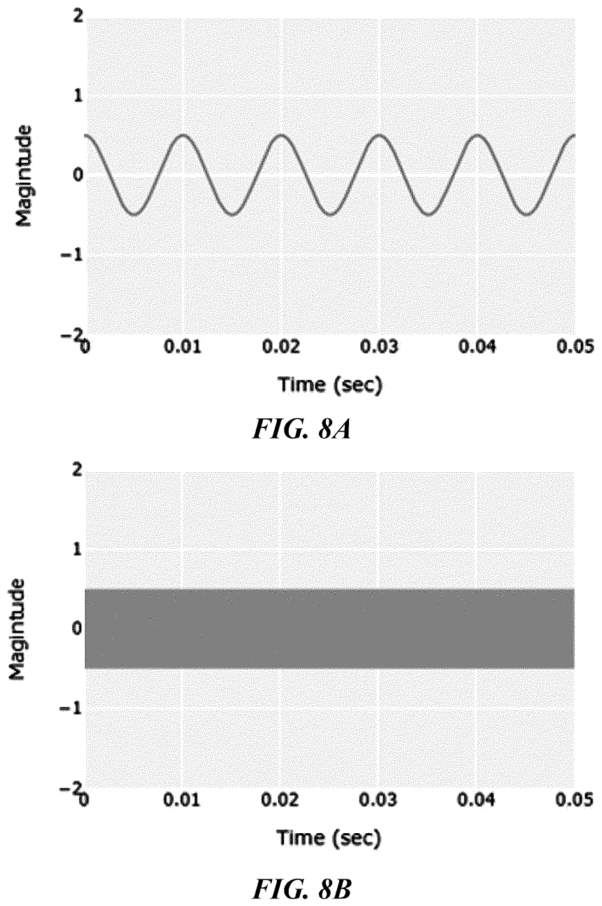

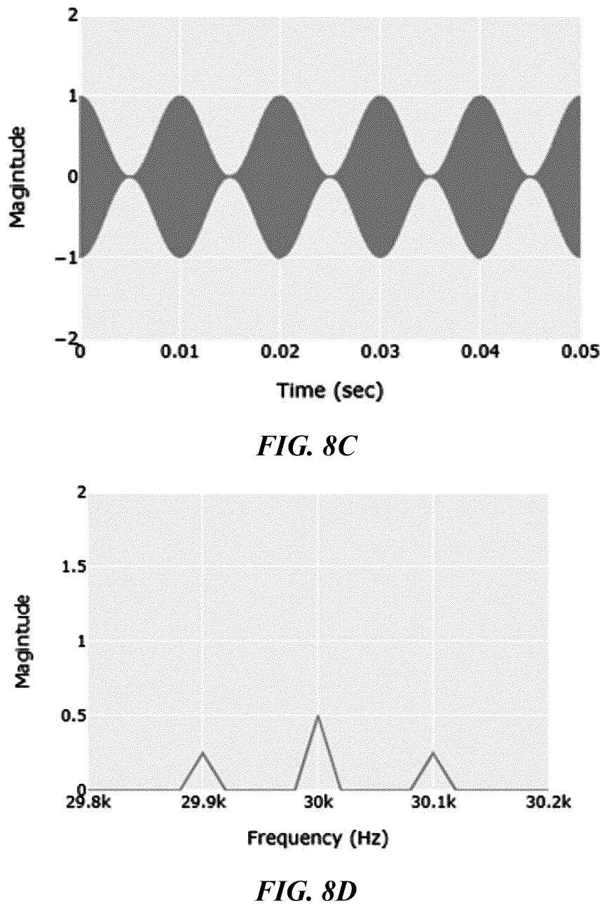

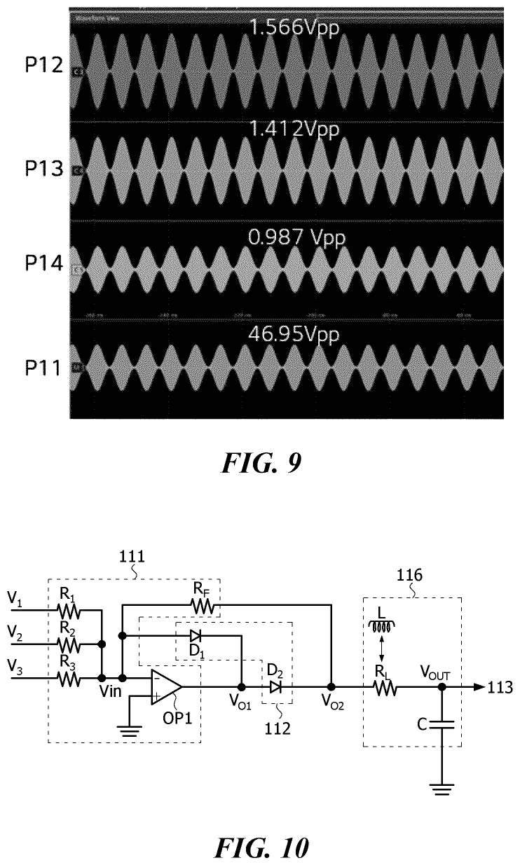

FIG. 7 is a diagram showing a panel member sample to which an experiment is applied to verify the energy recovery effect. In FIG. 7, reference symbol “P11” indicates the first vibration generator driven in vibration mode, and “P12 to P15” indicate a plurality of second vibration generators driven in energy harvest mode. FIGS. 8A to 8D are diagrams showing characteristics of the input signal and output signal of the first vibration generator driven in vibration mode. In FIGS. 8A to 8C, the horizontal axis represents time (second), and the vertical axis represents the magnitude of vibration. In FIG. 8D, the horizontal axis represents frequency (hertz (Hz)), and the vertical axis represents the magnitude of vibration. FIG. 9 is a diagram showing the waveform of an electric signal output by the piezoelectric effect from the second vibration generators in the sample illustrated in FIG. 7.

With reference to FIGS. 7 to 9, in the experiment, a vibration signal may be input to the first vibration generator P11, so that the first vibration generator P11 may vibrate due to the converse piezoelectric effect. In association with the vibration of the first vibration generator P11, the vibration may be transferred to the second vibration generators P12 to P15 through the panel member 300.

The vibration signal s(t) may be modulated as follows and input to the first vibration generator P11, wherein this vibration signal s(t) may be used as a haptic signal:

$$s ( t ) = Ac [ 1 + μcos ( 2 π {f}_{m} t ) ] cos ( 2 π {f}_{c} t ) where Ac = 0.5 , μ = 1 , {f}_{m} = 150 Hz , {f}_{c} = 60 kHz .$$

Here, Ac is the amplitude of the carrier, fₘ is the modulation frequency, f_{c} is the carrier frequency, t is time, and u is the modulation depth. FIG. 8A is a measured waveform of an input signal of 100 Hz before modulation, and FIG. 8B is a measurement value of a carrier signal of 30 KHz. FIG. 8C is a measured waveform of the modulation signal s(t). The Vᵣₘₛ of the modulated vibration signal s(t) is 0.43. FIG. 8D is a frequency spectrum measured through fast Fourier transform (FFT).

The input voltage of the first vibration generator P11 and the Vpp (peak-to-peak voltage) of the electric signal output from the second vibration generators P12 to P14 through the piezoelectric effect were measured as shown in FIG. 9. The Vpp is the voltage difference between the lowest voltage and highest voltage of an AC signal. According to those identified in this experiment, sufficient energy is recovered from the non-vibrating second vibration generators P12 to P15, and the energy recovery effect may be further improved if the electric signals output from the second vibration generators P12 to P15 are summed.

In the experiment, the energy recovery effect has been verified even when the panel member 300 was configured as the panel member of a sound output device. The audible frequency may be in the range of 20 Hz to 20,000 Hz, but embodiments of the present disclosure are not limited thereto. When a 500 Hz sine wave input signal (83.40 Vpp) was input to the vibration generator P11 controlled in vibration mode, the Vpp measured values of the vibration generators P12 to P15 controlled in energy harvest mode were P12=214.9 mVpp, P13=143.0 mVpp, and P14=147.7 mVpp. In the case of 500 Hz sine wave input, the reason why the electric signal output from P14 is larger than P13 is because the position of P14 at 500 Hz is an antinode. When a 1 kHz sine wave input signal (83.22 Vpp) was input to the first vibration generator P11, the Vpp measurement values of the vibration generators P12 to P15 controlled in energy harvest mode were P12=187.1 mVpp, P13-152.5 mVpp, and P14=125.6 mVpp. Therefore, the energy recovery effect was confirmed even when the panel member 300 was used as a sound output device.

The summing circuit 111, rectifying circuit 112, and low-pass filter (LPF) of the energy recovery circuit 110 may be implemented with a summing and rectification integrated circuit as shown in FIG. 10.

FIG. 10 is a circuit diagram showing the summing and rectification integrated circuit according to an embodiment of the present disclosure.

With reference to FIG. 10, the summing and rectification integrated circuit may include a summing circuit 111, a rectifying circuit 112, and a low-pass filter 116.

The summing circuit 111 may be implemented with an inverting summer. The summing circuit may include an operational amplifier OP1, resistors R₁, R₂ and R₃ connected to the inverting input terminal (−) of the operational amplifier OP1, and a feedback resistor R_{F} connected between the output terminal of the operational amplifier OP1 and the inverting input terminal (−). A reference voltage or ground voltage may be applied to the non-inverting input terminal of the operational amplifier OP1. The output voltage V_{O1} of the summing circuit 111 is given by Equation 1.

$${V}_{01} = - [ \frac{{R}_{F}}{{R}_{1}} {V}_{1} + \frac{{R}_{F}}{{R}_{2}} {V}_{2} + \frac{{R}_{F}}{{R}_{3}} {V}_{3} ] = {R}_{F} [ \frac{{V}_{1}}{{R}_{1}} + \frac{{V}_{2}}{{R}_{2}} + \frac{{V}_{3}}{{R}_{3}} ] \qquad Equation 1$$

Input signals V₁, V₂ and V₃ of an AC waveform output from the vibration generators controlled in energy harvest mode may be input through the resistors R₁, R₂ and R₃ to the inverting input terminal (−) of the operational amplifier OP1. When the gain or amplification ratio is 1, i.e.,

$$\frac{{R}_{F}}{{R}_{1}} = \frac{{R}_{F}}{{R}_{2}} = \frac{{R}_{F}}{{R}_{3}} = 1 ,$$

the output voltage VO1 is a simple sum, V₁+V₂+V₃, of the input signals V₁, V₂ and V₃. By adjusting the amplification ratio of the summing circuit, the input signals may be summed in various forms to generate the sum signal.

The rectifying circuit 112 may be connected to the input terminal and the output terminal of the operational amplifier OP1. The rectifying circuit 112 may be implemented with a half-wave rectifying circuit integrated into the summing circuit. The rectifying circuit may include a first diode D₁ and a second diode D₂. The first diode D₁ may include an anode electrode connected to the inverting input terminal (−) of the operational amplifier OP1 and a cathode electrode connected to the output terminal of the operational amplifier OP1. The second diode D₂ may include an anode electrode connected to the output terminal of the operational amplifier OP1 and a cathode electrode connected to the low-pass filter 116.

As shown in Table 1 below, the first diode D₁ may be turned on when the summed input signal Vin is a positive voltage (or, positive polarity voltage) and the output voltage V_{O1} of the operational amplifier OP1 is a negative voltage (or, negative polarity voltage), and may be turned off when the input signal Vin is a negative voltage and the output voltage V_{O1} of the operational amplifier OP1 is a positive voltage. As shown in Table 1 below, the second diode D₂ may be turned on when the input signal Vin is a negative voltage and the output voltage V_{O1} of the operational amplifier OP1 is a positive voltage, and may be turned off when the input signal Vin is a positive voltage and the output voltage V_{O1} of the operational amplifier OP1 is a negative voltage.

The rectifying circuit 112 may block the input signal Vin so as not to transfer the input signal Vin to the low-pass filter 116 when the input signal Vin of an AC waveform is a positive voltage, and may supply a signal in which the input signals V₁, V₂ and V₃ are summed as shown in Equation 1 and Table 1 to the low-pass filter 116 when the input signal Vin is a negative voltage.

The low-pass filter 116 may be connected to the cathode electrode of the second diode D₂. The low-pass filter 116 may include a filter resistor R_{L} or inductor L connected to the cathode electrode of the second diode D₂, and a capacitor C connected to the filter resistor R_{L} or inductor L, but embodiments of the present disclosure are not limited thereto. The final output voltage Vout output through the node between the filter resistor R_{L} or inductor L and the capacitor C may be supplied to the charging circuit 113. The inductor L has high impedance at high frequency signals, so it may reduce high frequency noise more effectively than the resistor R_{L}, and may reduce energy consumption and heat generation compared to the resistor.

TABLE 1

| Vin | Vₒ₁ | D₁ | D₂ | V_{O2} |
|---|---|---|---|---|
| Positive | Negative | ON | OFF | |
| Negative | Positive | OFF | ON | −[R_{F} *[(1/R₁) * V₁ + R_{F} *[(1/R₂) * |
| | | | | V₂ + R_{F} *[(1/R₃) * V₃] |

As a result of the experiment on the summing and rectification integrated circuit shown in FIG. 10, when the input signals were V₁=0.75 V, V₂=0.7 V, V₃=0.5 V, and the amplification ratio was 2, the final output voltage Vout of the summing and rectification integrated circuit was measured to be a DC voltage of 3.3 V.

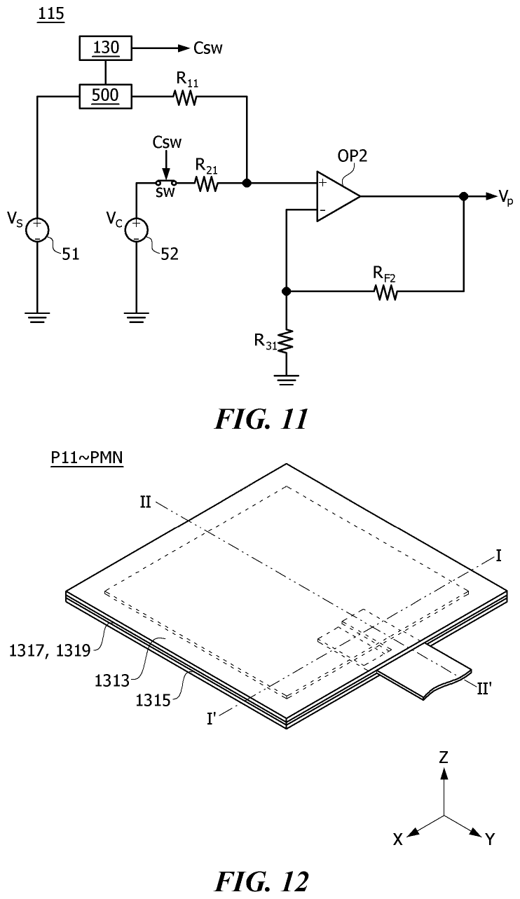

The second summing circuit 115 illustrated in FIG. 4 may be implemented with the summing and selection circuit shown in FIG. 11. FIG. 11 is a circuit diagram showing the summing and selection circuit according to an embodiment of the present disclosure.

With reference to FIG. 11, the summing and selection circuit may include an operational amplifier OP2, resistors R₁₁ and R₂₁ connected to the non-inverting input terminal (+) of the operational amplifier OP2, a feedback resistor R_{F2} connected between the output terminal of the operational amplifier OP2 and the inverting input terminal (−), a resistor R₃₁ connected between the inverting input terminal (−) of the operational amplifier OP2 and the ground voltage (or, reference voltage), a voltage detection circuit 500 connected between a first input voltage source 51 and the first resistor R₁₁, and a switch element SW connected between the second input voltage source 52 and the second resistor R₂₁, but embodiments of the present disclosure are not limited thereto.

The first input voltage source 51 may output a first voltage Vs. The first input voltage source 51 may be an external power source. The second input voltage source 52 may output a second voltage Vc. The second input voltage source 52 may be a battery of the charging circuit 113 or the voltage stabilizing circuit 114. The second voltage Vc may be an energy recovery voltage obtained through the vibration generators controlled in energy harvest mode.

The voltage detection circuit 500 detects the first voltage Vs applied to the first resistor R₁₁ in real time and supplies it to the control part 130. The control part 130 may compare the voltage level of the first voltage Vs detected by the voltage detection circuit 500 with a preset reference value and control the output voltage in first voltage output mode if the voltage level of the first voltage Vs detected by the voltage detection circuit 500 is higher than or equal to the reference value. The control part 130 may control the output voltage in second voltage output mode if the voltage level of the first voltage Vs detected by the voltage detection circuit 500 is lower than the reference value. The control part 130 may control the switch element SW by using a switch control signal Csw.

In first voltage output mode, the switch element SW may be turned off in response to the inactive logic value of the switch control signal Csw. Hence, in first voltage output mode, the output voltage Vp may be output as a voltage Vp=[(1+R_{F2}/R₃₁)]*Vs, R₁₁=R₂₁, which is the voltage obtained by applying the gain or amplification ratio (R_{F2}/R₃₁) of the operational amplifier OP2 to the first voltage Vs.

In second voltage output mode, the switch element SW may be turned on in response to the active logic value of the switch control signal Csw. Hence, in second voltage output mode, the output voltage Vp may be output as a voltage Vp=[(1+R_{F2}/R₃₁)]*(Vs+Vc)/2, R₁₁=R₂₁, which is a voltage obtained by adding the second voltage Vc to the first voltage Vs and applying the amplification ratio (R_{F2}/R₃₁) of the operational amplifier OP2. The output voltage Vp may be applied as a driving voltage to the vibration generators or may be used as a driving voltage to drive another electronic device connected to the power supply system.

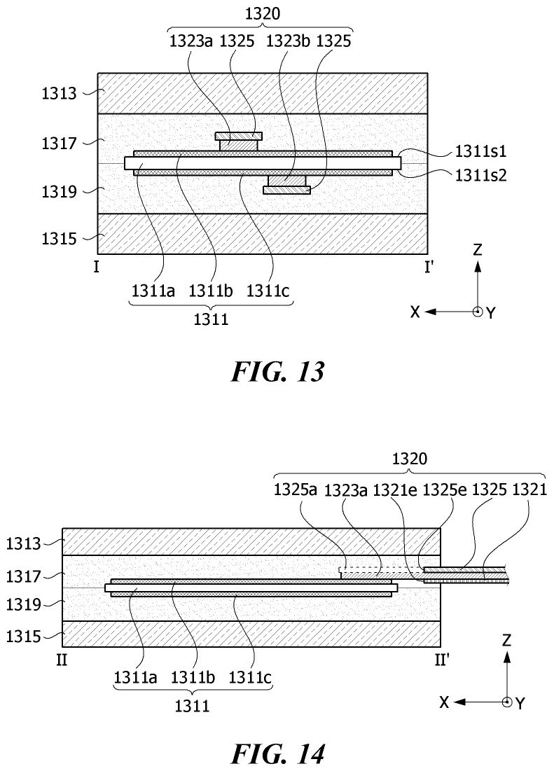

FIG. 12 is a diagram showing a vibration generator according to an embodiment of the present disclosure. FIG. 13 is a cross-sectional view showing the cross-sectional structure of the vibration generator taken along line I-I′ in FIG. 12. FIG. 14 is a cross-sectional view showing the cross-sectional structure of the vibration generator taken along line II-II′ in FIG. 12.

With reference to FIGS. 12 to 14, the vibration generators P11 to PMN may include one or more vibrators 1311.

The vibrator 1311 may provide a piezoelectric effect and a converse piezoelectric effect. The vibrator 1311 may vibrate according to the vibration (or, displacement or driving) of a piezoelectric material in response to the vibration signal applied to the piezoelectric material. For example, the vibrator 1311 may generate electricity when vibration occurs due to the piezoelectric effect (or, piezoelectric properties). The vibrator 1311 may vibrate in the Z-axis direction in response to an electrical vibration signal according to the converse piezoelectric effect.

The vibrator 1311 may be a vibration generating element, a vibration film, a vibration generating film, an active vibrator, an active vibration generator, an actuator, an exciter, a film actuator, a film exciter, an ultrasonic actuator, or an active vibration member, but embodiments of the present disclosure are not limited thereto.

The vibrator 1311 may be a vibration element, a piezoelectric element, a piezoelectric element unit, a piezoelectric element layer, a piezoelectric structure, a piezoelectric vibrating layer, or a piezoelectric vibrating layer, but embodiments of the present disclosure are not limited thereto.

The vibrator 1311 may include a vibration layer 1311a, a first electrode 1311b, and a second electrode 1311c.

The vibration layer 1311a may include a piezoelectric material or an electroactive material having a piezoelectric effect. For example, the vibration layer 1311a may be a piezoelectric layer, a piezoelectric material layer, an electroactive layer, a piezoelectric composite layer, a piezoelectric composite, or a piezoelectric ceramic composite, but embodiments of the present disclosure are not limited thereto.

The vibration layer 1311a may be composed of a ceramic-based piezoelectric ceramic capable of realizing relatively strong vibration, or may be composed of a piezoelectric ceramic having a perovskite crystal structure. For example, the vibration layer 1311a may include at least one of PbTiO₃, PbZrO₃, PbZrTiO₃, BaTiO₃, and SrTiO₃, but embodiments of the present disclosure are not limited thereto.

The piezoelectric ceramic may be composed of a single crystal ceramic having a single crystal structure, or may be composed of a ceramic material having a polycrystalline structure or a polycrystalline ceramic. The piezoelectric material of the single crystal ceramic may include α-AlPO₄, α-SiO₂, LiNbO₃, Tb₂(MoO₄)₃, Li₂B₄O₇, or ZnO, but embodiments of the present disclosure are not limited thereto. The piezoelectric material of the polycrystalline ceramic may include a PZT (lead zirconate titanate) based material including lead (Pb), zirconium (Zr), and titanium (Ti), or a PZNN (lead zirconate nickel niobate) based material including lead (Pb), zirconium (Zr), nickel (Ni), and niobium (Nb), but embodiments of the present disclosure are not limited thereto. For example, the vibration layer 1311a may include at least one of CaTiO₃, BaTiO₃, and SrTiO₃ that do not contain lead (Pb), but embodiments of the present disclosure are not limited thereto.

The first electrode 1311b may be disposed on the first surface (or, upper surface or front surface) 1311s1 of the vibration layer 1311a. The first electrode 1311b may have the same size as the vibration layer 1311a or a smaller size than the vibration layer 1311a, but embodiments of the present disclosure are not limited thereto.

The second electrode 1311c may be disposed on the second surface (or, lower surface or rear surface) 1311s2 different from or opposite to the first surface 1311s1 of the vibration layer 1311a. The second electrode 1311c may have the same size as the vibration layer 1311a or may have a smaller size than the vibration layer 1311a, but embodiments of the present disclosure are not limited thereto. For example, the second electrode 1311c may have the same shape as the vibration layer 1311a, but embodiments of the present disclosure are not limited thereto.

According to an embodiment of the present disclosure, at least one of the first electrode 1311b and the second electrode 1311c may be made of a transparent conductive material, a semitransparent conductive material, or an opaque conductive material. For example, the transparent or semitransparent conductive material may include indium tin oxide (ITO) or indium zinc oxide (IZO), but embodiments of the present disclosure are not limited thereto. The opaque conductive material may include gold (Au), silver (Ag), platinum (Pt), palladium (Pd), molybdenum (Mo), magnesium (Mg), carbon, or silver (Ag) containing glass frit, or may be made of an alloy thereof, but embodiments of the present disclosure are not limited thereto. For example, each of the first electrode 1311b and the second electrode 1311c may include silver (Ag) having low resistivity to improve the electrical characteristics and/or vibration characteristics of the vibration layer 1311a. For example, the carbon may be a carbon material including carbon black, ketjen black, carbon nanotubes, and graphite, but embodiments of the present disclosure are not limited thereto.

The vibration layer 1311a may be polarized (or poled) with a constant voltage applied to the first electrode 1311b and the second electrode 1311c in a constant temperature atmosphere or a temperature atmosphere that changes from high temperature to room temperature, but embodiments of the present disclosure are not limited thereto. For example, the polarization direction (or poling direction) formed in the vibration layer 1311a may be formed or oriented (or arranged) from the first electrode 1311b to the second electrode 1311c, but without being limited thereto. For example, the polarization direction (or poling direction) formed in the vibration layer 1311a may be formed or oriented (or arranged) from the second electrode 1311c to the first electrode 1311b.

The vibration layer 1311a may vibrate by alternately repeating contraction and/or expansion due to the converse piezoelectric effect caused by the driving signal applied from the outside to the first electrode 1311b and the second electrode 1311c. For example, the vibration layer 1311a may vibrate in the Z-axis direction (or thickness direction) and the XY plane direction according to the signal applied to the first electrode 1311b and the second electrode 1311c.

The vibration generators P11 to PMN according to an embodiment of the present disclosure may further include a first cover member 1313 and a second cover member 1315. For another example, only one of the first cover member 1313 and the second cover member 1315 may be configured. For instance, the cover member may be formed on the first surface of the vibration generators P11 to PMN or the second surface of the vibration generators P11 to PMN.

The first cover member 1313 may be disposed on the first surface of the vibration generators P11 to PMN, for example on the first surface of the vibrator 1311, as shown FIG. 13. For example, the first cover member 1313 may be formed to cover the first electrode 1311b of the vibration generators P11 to PMN, for example the first electrode 1311b of the vibrator 1311. For example, the first cover member 1313 may be formed to have a larger size than the vibrator 1311, but embodiments of the present disclosure are not limited thereto. The first cover member 1313 may be formed to protect the first surface and first electrode 1311b of the vibrator 1311.

The second cover member 1315 may be disposed on the second surface of the vibration generators P11 to PMN, for example on the second surface of the vibrator 1311, as shown FIG. 13. For example, the second cover member 1315 may be formed to cover the second electrode 1311c of the vibration generators P11 to PMN, for example the second electrode 1311c of the vibrator 1311. For example, the second cover member 1315 may be formed to have a larger size than the vibrator 1311, and may be formed to have the same size as the first cover member 1313, but embodiments of the present disclosure are not limited thereto. The second cover member 1315 may be formed to protect the second surface and second electrode 1311c of the vibrator 1311.

According to an embodiment of the present disclosure, the first cover member 1313 and the second cover member 1315 may include the same or different materials. For example, each of the first cover member 1313 and the second cover member 1315 may be a polyimide film, a polyethylene terephthalate film, a polyethylene naphathalate film, or the like, but embodiments of the present disclosure are not limited thereto.

The first cover member 1313 may be connected or coupled to the first surface or the first electrode 1311b of the vibrator 1311 via the medium of the first adhesive layer 1317. For example, the first cover member 1313 may be connected or coupled to the first surface or the first electrode 1311b of the vibrator 1311 by a film laminating process using the first adhesive layer 1317 as a medium.

The second cover member 1315 may be connected or coupled to the second surface or the second electrode 1311c of the vibrator 1311 via the medium of the second adhesive layer 1319. For example, the second cover member 1315 may be connected or coupled to the second surface or second electrode 1311c of the vibrator 1311 by a film laminating process using the second adhesive layer 1319 as a medium.

According to an embodiment of the present disclosure, each of the first adhesive layer 1317 and the second adhesive layer 1319 may include an electrically insulating material that is adhesive and compressible and restorable. For example, each of the first adhesive layer 1317 and the second adhesive layer 1319 may include an epoxy resin, an acrylic resin, a silicone resin, a urethane resin, an acrylic-based polymer, a silicone-based polymer, or a urethane-based polymer, but embodiments of the present disclosure are not limited thereto.

The first adhesive layer 1317 and the second adhesive layer 1319 may be formed between the first cover member 1313 and the second cover member 1315 so as to surround the vibrator 1311. For example, at least one of the first adhesive layer 1317 and the second adhesive layer 1319 may be formed to partially or fully surround the vibrator 1311.

One of the first cover member 1313 and the second cover member 1315 may be omitted. For example, one of the first cover member 1313 and the second cover member 1315 may be formed to cover or protect at least one of the first surface and the second surface of the vibrator 1311.

The vibrator 1311 according to an embodiment of the present disclosure may further include a signal supply member 1320.

The signal supply member 1320 may be formed to supply a driving signal supplied from the driving circuit to the vibrator 1311. The signal supply member 1320 may be formed to be electrically connected to the first electrode 1311b and the second electrode 1131c of the vibration layer 1311a.

A portion of the signal supply member 1320 may be accommodated (or, inserted) between the first cover member 1313 and the second cover member 1315. The end portion (or, terminal portion or one side) of the signal supply member 1320 may be disposed or inserted (or, accommodated) between one edge portion of the first cover member 1313 and one edge portion of the second cover member 1315. One edge portion of the first cover member 1313 and one edge portion of the second cover member 1315 may accommodate or cover the end portion (or, terminal portion or one side) of the signal supply member 1320 from above and below. Thereby, the signal supply member 1320 may be integrated with the vibrator 1311. For example, the signal supply member 1320 may be formed as a single component with the vibrator 1311, thereby providing the effect of uni-materialization. For example, the signal supply member 1320 may be composed of a signal cable, a flexible cable, a flexible printed circuit cable, a flexible flat cable, a single-sided flexible printed circuit, a single-sided flexible printed circuit board, a flexible multilayer printed circuit, or a flexible multilayer printed circuit board, but embodiments of the present disclosure are not limited thereto.

The signal supply member 1320 according to an embodiment of the present disclosure may include a base member 1321, and a plurality of signal lines 1323a and 1323b. For example, the signal supply member 1320 may include a base member 1321, a first signal line 1323a, and a second signal line 1323b.

The base member 1321 may include a transparent or opaque plastic material, but embodiments of the present disclosure are not limited thereto. The base member 1321 may have a constant width along the first direction (X) and may be extended along the second direction (Y) intersecting the first direction (X).

The first signal line 1323a and the second signal line 1323b may be disposed on the first surface of the base member 1321 so as to be parallel to the second direction (Y), and may be spaced apart from each other or electrically separated from each other along the first direction (X). The first signal line 1323a and the second signal line 1323b may be arranged parallel to each other on the first surface of the base member 1321. For example, the first signal line 1323a and the second signal line 1323b may be implemented in a line shape by patterning a metal layer (or, conductive layer) formed or deposited on the first surface of the base member 1321, but embodiments of the present disclosure are not limited thereto.

The end portions (or, terminal portions or one sides) of the first signal line 1323a and the second signal line 1323b may be separated from each other to be individually warped or bent.

The end portion (or, terminal portion or one side) of the first signal line 1323a may be electrically connected to the first electrode 1311b of the vibrator 1311. For example, the end portion of the first signal line 1323a may be electrically connected to at least a portion of the first electrode 1311b of the vibrator 1311 at one edge portion of the first cover member 1313. For example, the end portion (or, terminal portion or one side) of the first signal line 1323a may be electrically connected directly to at least a portion of the first electrode 1311b of the vibrator 1311. For example, the end portion (or, terminal portion or one side) of the first signal line 1323a may be directly connected to or in direct contact with the first electrode 1311b of the vibrator 1311. For example, the end portion of the first signal line 1323a may be electrically connected to the first electrode 1311b through a conductive double-sided tape. Consequently, the first signal line 1323a may supply the vibration signal supplied from the driving part to the first electrode 1311b of the vibrator 1311.

The end portion (or, terminal portion or one side) of the second signal line 1323b may be electrically connected to the second electrode 1311c of the vibrator 1311. For example, the end portion of the second signal line 1323b may be electrically connected to at least a portion of the second electrode 1311c of the vibrator 1311 at one edge portion of the second cover member 1315. For example, the end portion of the second signal line 1323b may be electrically connected directly to at least a portion of the second electrode 1311c of the vibrator 1311. For example, the end portion of the second signal line 1323b may be directly connected to or in direct contact with the second electrode 1311c of the vibrator 1311. For example, the end portion of the second signal line 1323b may be electrically connected to the second electrode 1311c through a conductive double-sided tape. Consequently, the second signal line 1323b may supply a vibration signal supplied from the driving part to the second electrode 1311c of the vibrator 1311.

The signal supply member 1320 according to an embodiment of the present disclosure may further include an insulating layer 1325.

The insulating layer 1325 may be disposed on the first surface of the base member 1321 so as to separately cover the first signal line 1323a and the second signal line 1323b except for the end portion (or, one side) of the signal supply member 1320.

The end portion (or, one side) of the signal supply member 1320 including the end portion (or, one side) of the base member 1321, and the end portion (or, one side) 1325a of the insulating layer 1325 may be inserted (or, accommodated) between the first cover member 1313 and the second cover member 1315, and may be fixed between the first cover member 1313 and the second cover member 1315 by the first adhesive layer 1317 and the second adhesive layer 1319. Thereby, the end portion (or, one side) of the first signal line 1323a may be maintained in a state of being electrically connected to the first electrode 1311b of the vibrator 1311, and the end portion (or one side) of the second signal line 1323b may be maintained in a state of being electrically connected to the second electrode 1311c of the vibrator 1311. In addition, since the end portion (or one side) of the signal supply member 1320 is inserted (or accommodated) and fixed between the vibrator 1311 and the first cover member 1313, a bad connection between the vibrator 1311 and the signal supply member 1320 due to movement of the signal supply member 1320 may be prevented.

In the signal supply member 1320 according to an embodiment of the present disclosure, both the end portion (or one side) of the base member 1321 and the end portion (or one side) 1325a of the insulating layer 1325 may be removed. For example, both the end portion (or one side) of the first signal line 1323a and the end portion (or one side) of the second signal line 1323b may be exposed to the outside without being supported or covered respectively by the end portion (or one side) of the base member 1321 and the end portion (or one side) 1325a of the insulating layer 1325. For example, the end portion (or one side) of the first signal line 1323a and the end portion (or one side) of the second signal line 1323b may protrude (or be extended) to have a specific length from the end portion 1321e of the base member 1321 or the end portion 1325e of the insulating layer 1325. Thereby, the end portions (or, terminal portions or one sides) of the first signal line 1323a and the second signal line 1323b may be individually or independently warped or bent.

The end portion (or, one side) of the first signal line 1323a that is not supported by the end portion (or, one side) of the base member 1321 or the end portion (or, one side) 1325a of the insulating layer 1325 may be directly connected to or in direct contact with the first electrode 1311b of the vibrator 1311. The end portion (or, one side) of the second signal line 1323b that is not supported by the end portion (or, one side) of the base member 1321 or the end portion (or, one side) 1325a of the insulating layer 1325 may be directly connected to or in direct contact with the second electrode 1311c of the vibrator 1311.

According to an embodiment of the present disclosure, a portion of the signal supply member 1320 or a portion of the base member 1321 may be disposed or inserted (or, accommodated) between the first cover member 1313 and the second cover member 1315, so that the signal supply member 1320 may be integrated with the vibrator 1311. Thereby, the vibrator 1311 and the signal supply member 1320 may be formed as a single component, achieving the effect of uni-materialization.

According to an embodiment of the present disclosure, since the first signal line 1323a and the second signal line 1323b of the signal supply member 1320 are integrated with the vibrator 1311, a soldering process for electrical connection between the vibrator 1311 and the signal supply member 1320 is not required, and therefore, the structure and manufacturing process of the vibrator 1333 may be simplified, thereby resulting in an effect of avoiding a harmful process.

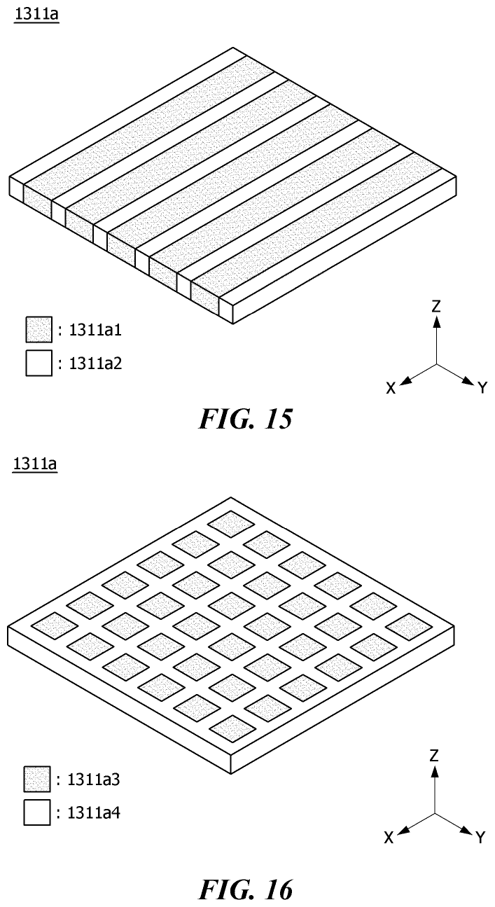

FIG. 15 is a diagram showing a vibration layer according to another embodiment of the present disclosure. For example, FIG. 15 illustrates another embodiment of the vibration layer described with reference to FIGS. 12 to 14.

With reference to FIG. 13 and FIG. 15, the vibration layer 1311a according to another embodiment of the present disclosure may include a plurality of first parts 1311a1 and a plurality of second parts 1311a2. For example, the plural first parts 1311a1 and the plural second parts 1311a2 may be alternately and repeatedly arranged along the X-axis direction (or, first direction) or the Y-axis direction (or, second direction).

Each of the plural first parts 1311a1 may include an inorganic material having a piezoelectric effect and a converse piezoelectric effect. For example, each of the plural first parts 1311a1 may include at least one of a piezoelectric inorganic material and a piezoelectric organic material. For example, each of the plural first parts 1311a1 may be an inorganic part, an inorganic material part, a piezoelectric part, a piezoelectric material part, or an electrically active part, but embodiments of the present disclosure are not limited thereto.

According to an embodiment of the present disclosure, each of the plural first parts 1311a1 may have a width parallel to the second direction (Y) (or, first direction (X)) and may be extended along the first direction (X) (or, second direction (Y)). Each of the plural first parts 1311a1 is substantially identical to the vibration layer 1311a described with reference to FIGS. 12 to 14, and a repeated description thereof may be omitted or simplified.

The plural second parts 1311a2 may be disposed between the plural first parts 1311a1. For example, each of the plural first parts 1311a1 may be disposed between two adjacent second parts 1311a2 among the plural second parts 1311a2. Each of the plural second parts 1311a2 may have a width parallel to the second direction (Y) (or, first direction (X)) and may be extended along the first direction (X) (or, second direction (Y)). The width of the first part 1311a1 may be the same as or different from the width of the second part 1311a2. For example, the width of the first part 1311a1 may be greater than the width of the second part 1311a2. For example, the first part 1311a1 and the second part 1311a2 may include line shapes or stripe shapes having the same or different sizes, but embodiments of the present disclosure are not limited thereto.

Each of the plural second parts 1311a2 may be formed to fill a gap between two adjacent first parts 1311a1. Each of the plural second parts 1311a2 may be formed to fill a gap between two adjacent first parts 1311a1 so as to be connected or bonded to the side surface of the adjacent first part 1311a1. According to an embodiment of the present disclosure, the plural first parts 1311a1 and the plural second parts 1311a2 may be disposed (or, arranged) in parallel to each other on the same plane (or, same layer). Thereby, the vibration layer 1311a may be expanded to a desired size or length by lateral coupling (or, connection) between the first parts 1311a1 and the second parts 1311a2.

According to an embodiment of the present disclosure, each of the plural second parts 1311a2 may improve the durability of the first part 1311a1 by absorbing the impact applied to the first part 1311a1 and may provide flexibility to the vibration layer 1311a. Each of the plural second parts 1311a2 may include an organic material having a ductile property. For example, the plural second parts 1311a2 may be at least one of an epoxy based polymer, an acrylic based polymer, and a silicone based polymer, but embodiments of the present disclosure are not limited thereto. For example, each of the plural second parts 1311a2 may be an organic part, an organic material part, an adhesive part, a stretchable part, a bendable part, a damping part, or a flexible part, but embodiments of the present disclosure are not limited thereto.

The first surface of each of the plural first parts 1311a1 and the plural second parts 1311a2 may be commonly connected to the first electrode 1311b. The second surface of each of the plural first parts 1311a1 and the plural second parts 1311a2 may be commonly connected to the second electrode 1311c. For example, one or both of the first electrode 1311b and the second electrode 1311c may be formed as a pattern-shaped electrode so as to correspond only to the plural first parts 1311a1.

The vibration layer 1311a according to another embodiment of the present disclosure may have a single thin film shape by arranging (or, connecting) the plural first parts 1311a1 and the plural second parts 1311a2 on the same plane. Thereby, the vibration generators P11 to PMN according to another embodiment of the present disclosure may vibrate by using the first parts 1311a1 of the vibration layer 1311a having vibration characteristics, and may be bent in a curved shape by using the second parts 1311a2 having flexibility.

FIG. 16 is a diagram showing a vibration layer according to another embodiment of the present disclosure. For example, FIG. 16 illustrates another embodiment of the vibration layer described with reference to FIGS. 12 to 14.

With reference to FIGS. 13 and 16, the vibration layer 1311a according to another embodiment of the present disclosure may include a plurality of first parts 1311a3 and a second part 1311a4 disposed between the plural first parts 1311a3.

The plural first parts 1311a3 may be arranged to be spaced apart from each other along the first direction (X) and the second direction (Y). For example, the plural first parts 1311a3 may have hexahedral shapes of the same size and may be arranged in a grid shape, but embodiments of the present disclosure are not limited thereto. For example, the plural first parts 1311a3 may each have circular, elliptical, or polygonal plate shapes of the same size, but embodiments of the present disclosure are not limited thereto.

The plural first parts 1311a3 are each substantially identical to the first parts 1311a1 described with reference to FIG. 15, and a repeated description thereof may be omitted or simplified.

The second part 1311a4 may be arranged between the plural first parts 1311a3 along the first direction (X) and the second direction (Y). The second part 1311a4 may be formed to fill a gap between two adjacent first parts 1311a3, or to be adjacent to each of the plural first parts 1311a3, or to surround each of the plural first parts 1311a3, thereby being connected or bonded to the adjacent first parts 1311a3. The second part 1311a4 is substantially identical to the second part 1311a2 described with reference to FIG. 15, and a repeated description thereof may be omitted or simplified.

The first surface of each of the plural first parts 1311a3 and the second part 1311a4 may be commonly connected to the first electrode 1311b. The second surface of each of the plural first parts 1311a3 and the second part 1311a4 may be commonly connected to the second electrode 1311c. According to another embodiment of the present disclosure, at least one of the first electrode 1311b and the second electrode 1311c may be formed in the shape of a patterned electrode corresponding only to the plural first parts 1311a3.

The vibration layer 1311a according to another embodiment of the present disclosure may have a single thin film shape by arranging (or connecting) the plural first parts 1311a3 and the second part 1311a4 on the same plane. Thereby, the vibration generators P11 to PMN according to another embodiment of the present disclosure may vibrate by using the first parts 1311a3 of the vibration layer 1311a having vibration characteristics, and may be bent in a curved shape by using the second part 1311a4 having flexibility.

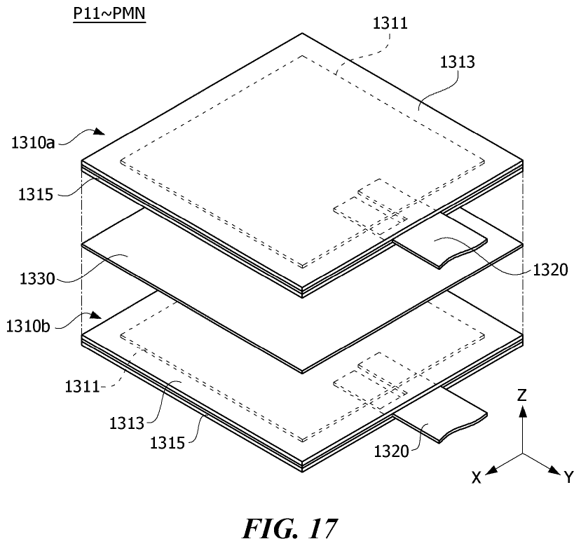

FIG. 17 is a diagram showing a vibration generator according to another embodiment of the present disclosure.

With reference to FIG. 17, the vibration generators P11 to PMN according to another embodiment of the present disclosure may include a plurality of vibration generators 1310a and 1310b stacked in the Z-axis direction (or, third direction). Each of the first vibration generator 1310a and the second vibration generator 1310b may include a vibrator 1311.

The first vibration generator 1310a and the second vibration generator 1310b may have substantially the same size, but embodiments of the present disclosure are not limited thereto. Thereby, the first vibration generator 1310a and the second vibration generator 1310b may maximize the amplitude displacement of the vibration generators P11 to PMN.

The vibrator 1311 of each of the first vibration generator 1310a and the second vibration generator 1310b is identical or substantially identical to the vibrator of the vibration generators P11 to PMN described with reference to FIGS. 12 to 16, so the same reference symbols may be assigned thereto, and repeated descriptions may be omitted or simplified.

The vibration generators P11 to PMN according to another embodiment of the present disclosure may further include an intermediate member 1330.

The intermediate member 1330 may be disposed or connected between the first vibration generator 1310a and the second vibration generator 1310b. For example, the intermediate member 1330 may be disposed or connected between the second cover member 1315 of the first vibration generator 1310a and the first cover member 1313 of the second vibration generator 1310b. For example, the intermediate member 1330 may be an adhesive member or a connecting member, but embodiments of the present disclosure are not limited thereto.

The intermediate member 1330 according to an embodiment of the present disclosure may be made of a material including an adhesive layer having excellent adhesion or adhesive strength for both of the first vibration generator 1310a and the second vibration generator 1310b. For example, the intermediate member 1330 may include a foam pad, a double-sided tape, a double-sided foam tape, a double-sided pad, a double-sided foam pad, or an adhesive, but embodiments of the present disclosure are not limited thereto. For example, the adhesive layer of the intermediate member 1330 may include epoxy, acrylic, silicone, or urethane, but embodiments of the present disclosure are not limited thereto. For example, the adhesive layer of the intermediate member 1330 may include a urethane based material (or, substance) having relatively ductile properties. Thereby, vibration loss due to displacement interference between the first vibration generator 1310a and the second vibration generator 1310b may be minimized, or each of the first vibration generator 1310a and the second vibration generator 1310b may be freely displaced (or, vibrated or driven).

The vibration generators P11 to PMN according to another embodiment of the present disclosure includes the first vibration generator 1310a and the second vibration generator 1310b that are stacked (or, overlapped or superimposed) to be vibrated (or, displaced or driven) in the same direction, so the displacement amount or the amplitude displacement may be maximized or increased. Thereby, the displacement amount (or, bending force or driving force) or amplitude displacement of the vibration generators P11 to PMN may be maximized or increased.

According to one or more embodiments of the present disclosure, an energy recovery circuit and a power supply system including the same may be described as follows.

According to one or more embodiments of the present disclosure, an energy recovery circuit may include a summing circuit configured to amplify or sum electricity output from one or more vibration generators in response to vibration of a panel member; a rectifying circuit configured to rectify an output signal of the summing circuit; and a charging circuit configured to charge with electricity output from the rectifying circuit.

According to one or more embodiments of the present disclosure, the energy recovery circuit may further include a voltage stabilizing circuit configured to stabilize a voltage from the charging circuit through a regulator.

According to one or more embodiments of the present disclosure, the energy recovery circuit may further include a second summing circuit configured to sum the voltage from the charging circuit and an external voltage or an output voltage of the voltage stabilizing circuit and the external voltage. An output voltage of the second summing circuit may be applied to the vibration generators or another electronic device.

According to one or more embodiments of the present disclosure, an energy recovery circuit may include summing and rectification circuit configured to amplify or sum and rectify electricity output from a plurality of vibration generators in response to vibration of a panel member; and a charging circuit configured to charge with a DC voltage output from the summing and rectification circuit.

According to one or more embodiments of the present disclosure, the summing and rectification circuit may include a summing circuit that includes an operational amplifier into which signals output from the plural vibration generators are input; and a rectifying circuit connected between an input terminal and an output terminal of the operational amplifier.

According to one or more embodiments of the present disclosure, the summing circuit may further include a plurality of resistors connected to an inverting input terminal of the operational amplifier; and a feedback resistor connected between the output terminal and the inverting input terminal of the operational amplifier. A reference voltage or ground voltage may be applied to a non-inverting input terminal of the operational amplifier.

According to one or more embodiments of the present disclosure, the rectifying circuit may include a first diode that includes an anode electrode connected to the inverting input terminal of the operational amplifier and a cathode electrode connected to the output terminal of the operational amplifier; and a second diode that includes an anode electrode connected to the output terminal of the operational amplifier and a cathode electrode.

According to one or more embodiments of the present disclosure, the summing and rectification circuit may further include a low-pass filter connected to the cathode electrode of the second diode.

According to one or more embodiments of the present disclosure, the low-pass filter may include a filter resistor connected to the cathode electrode of the second diode; and a capacitor connected to the filter resistor.

According to one or more embodiments of the present disclosure, the low-pass filter may include an inductor connected to the cathode electrode of the second diode; and a capacitor connected to the inductor.

According to one or more embodiments of the present disclosure, a power supply system may include a panel member on which a plurality of vibration generators are arranged; a control part that is configured to control, among the vibration generators arranged on the panel member, one or more first vibration generators in vibration mode and control one or more second vibration generators in energy harvest mode; a plurality of driving parts that are configured to vibrate the first vibration generators under the control of the control part and receive electricity output from the second vibration generators in response to vibration of the panel member; and an energy recovery circuit that is configured to charge with the electricity output from the second vibration generators through the driving parts.

According to one or more embodiments of the present disclosure, each of the driving parts may include a vibration driver configured to amplify a vibration signal input from the control part; a first switch element that is turned on under the control of the control part to supply the vibration signal output from the vibration driver to the first vibration generators operating in the vibration mode; an amplifier; and a second switch element that is turned on under the control of the control part to supply electricity output from the second vibration generators operating in the energy harvest mode to the amplifier.

According to one or more embodiments of the present disclosure, the driving parts may be connected respectively to different vibration generators or vibration generator groups. Each vibration generator group may include a plurality of vibration generators.

According to one or more embodiments of the present disclosure, the control part may output switch control signals that individually control the driving parts.

According to one or more embodiments of the present disclosure, the second vibration generators may output the electricity in response to vibration of the panel member.

According to one or more embodiments of the present disclosure, the energy recovery circuit may be connected to a plurality of second vibration generators. The energy recovery circuit may include a summing circuit configured to amplify or sum electricity output from the plural second vibration generators; a rectifying circuit configured to rectify an output signal of the summing circuit; and a charging circuit configured to charge with electricity output from the rectifying circuit.

According to one or more embodiments of the present disclosure, the energy recovery circuit further may include a voltage stabilizing circuit that stabilizes a voltage from the charging circuit through a regulator.

According to one or more embodiments of the present disclosure, the energy recovery circuit may further include a second summing circuit configured to sum the voltage from the charging circuit and an external voltage or an output voltage of the voltage stabilizing circuit and the external voltage. An output voltage of the second summing circuit may be applied to the vibration generators or another electronic device.

According to one or more embodiments of the present disclosure, the second summing circuit may include an operational amplifier; a first resistor connected to a non-inverting input terminal of the operational amplifier; a second resistor connected to the non-inverting input terminal of the operational amplifier; a feedback resistor connected between an output terminal and an inverting input terminal of the operational amplifier; a third resistor connected between the inverting input terminal of the operational amplifier and a ground voltage; a voltage detection circuit connected between a first voltage source outputting a first voltage and the first resistor; and a switch element connected between a second voltage source outputting a second voltage and the second resistor. The second voltage source may include a battery of the charging circuit or the voltage stabilizing circuit.

According to one or more embodiments of the present disclosure, the control part may turn off the switch element when the first voltage output from the voltage detection circuit is greater than or equal to a preset reference value, and turn on the switch element when the first voltage output from the voltage detection circuit is less than the reference value.

According to one or more embodiments of the present disclosure, the vibration generator may include at least one vibrator. At least one vibrator may include a vibration layer including a piezoelectric material; a first electrode on a first surface of the vibration layer; a second electrode on a second surface different from the first surface of the vibration layer; and a cover member on a first surface or second surface of the at least one vibrator.

According to one or more embodiments of the present disclosure, the energy recovery circuit and power supply system may be applied to mobile devices, video phones, smart watches, watch phones, wearable device, foldable device, rollable device, bendable device, flexible device, curved device, sliding device, variable device, electronic organizer, electronic books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances, etc. Additionally, the energy recovery circuit and power supply system according to one or more embodiments of the present disclosure may be applied to organic light emitting lighting devices or inorganic light emitting lighting devices.

The technical characteristics to be achieved by the present disclosure, the means for achieving the technical characteristics, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An energy recovery circuit comprising:
a first summing circuit configured to amplify or sum electricity output from one or more vibration generators in response to vibration of a panel member;
a rectifying circuit configured to rectify an output signal of the summing circuit; and
a charging circuit configured to charge with electricity output from the rectifying circuit.

2. The energy recovery circuit of claim 1, further comprising:
a voltage stabilizing circuit configured to stabilize a voltage from the charging circuit through a regulator.

3. The energy recovery circuit of claim 1, further comprising:
a second summing circuit configured to sum the voltage from the charging circuit and an external voltage or an output voltage of the voltage stabilizing circuit and the external voltage,
wherein an output voltage of the second summing circuit is applied to the vibration generators or another electronic device.

4. An energy recovery circuit comprising:
a summing and rectification circuit configured to amplify or sum and rectify electricity output from a plurality of vibration generators in response to vibration of a panel member; and
a charging circuit configured to charge with a DC voltage output from the summing and rectification circuit.

5. The energy recovery circuit of claim 4, wherein the summing and rectification circuit includes:
a summing circuit that includes an operational amplifier connected to receive signals from the plural vibration generators; and
a rectifying circuit connected between an input terminal and an output terminal of the operational amplifier.

6. The energy recovery circuit of claim 5, wherein the summing circuit further includes:
a plurality of resistors connected to an inverting input terminal of the operational amplifier; and
a feedback resistor connected between the output terminal and the inverting input terminal of the operational amplifier, and
wherein a non-inverting input terminal of the operational amplifier is connected to receive a reference voltage or a ground voltage.

7. The energy recovery circuit of claim 6, wherein the rectifying circuit includes:
a first diode that includes an anode electrode connected to the inverting input terminal of the operational amplifier and a cathode electrode connected to the output terminal of the operational amplifier; and
a second diode that includes an anode electrode connected to the output terminal of the operational amplifier and a cathode electrode.

8. The energy recovery circuit of claim 7, wherein the summing and rectification circuit further includes:
a low-pass filter connected to the cathode electrode of the second diode.

9. The energy recovery circuit of claim 8, wherein the low-pass filter includes:
a filter resistor connected to the cathode electrode of the second diode; and
a capacitor connected to the filter resistor.

10. The energy recovery circuit of claim 8, wherein the low-pass filter includes:
an inductor connected to the cathode electrode of the second diode; and
a capacitor connected to the inductor.

11. A power supply system comprising:
a panel member on which a plurality of vibration generators are arranged;
a control part that is configured to control, among the vibration generators arranged on the panel member, one or more first vibration generators in vibration mode, and control one or more second vibration generators in energy harvest mode;
a plurality of driving parts that are configured to vibrate the one or more first vibration generators under the control of the control part and receive electricity output from the one or more second vibration generators in response to vibration of the panel member; and
an energy recovery circuit that is configured to charge with the electricity output from the second vibration generators through the driving parts.

12. The power supply system of claim 11, wherein each of the driving parts includes:
a vibration driver configured to amplify a vibration signal input from the control part;
a first switch element configured to be turned on under the control of the control part to supply the vibration signal output from the vibration driver to the first vibration generators operating in the vibration mode;
an amplifier; and
a second switch element configured to be turned on under the control of the control part to supply electricity output from the second vibration generators operating in the energy harvest mode to the amplifier.

13. The power supply system of claim 12, wherein:
the driving parts are connected respectively to different vibration generators or vibration generator groups; and
each vibration generator group includes a plurality of vibration generators.

14. The power supply system of claim 13, wherein the control part is configured to output switch control signals that individually control the driving parts.

15. The power supply system of claim 11, wherein the second vibration generators are configured to output the electricity in response to vibration of the panel member.

16. The power supply system of claim 15, wherein:
the energy recovery circuit is connected to a plurality of second vibration generators; and
the energy recovery circuit includes:
a summing circuit configured to amplify or sum electricity output from the plural second vibration generators;
a rectifying circuit configured to rectify an output signal of the summing circuit; and
a charging circuit configured to charge with electricity output from the rectifying circuit.

17. The power supply system of claim 16, wherein the energy recovery circuit further includes:
a voltage stabilizing circuit that stabilizes a voltage from the charging circuit through a regulator.

18. The power supply system of claim 16, wherein the energy recovery circuit further includes:
a second summing circuit configured to sum the voltage from the charging circuit and an external voltage or an output voltage of the voltage stabilizing circuit and the external voltage, and
wherein an output voltage of the second summing circuit is configured to be applied to the vibration generators or another electronic device.

19. The power supply system of claim 18, wherein the second summing circuit includes:
an operational amplifier;
a first resistor connected to a non-inverting input terminal of the operational amplifier;
a second resistor connected to the non-inverting input terminal of the operational amplifier;
a feedback resistor connected between an output terminal and an inverting input terminal of the operational amplifier;
a third resistor connected between the inverting input terminal of the operational amplifier and a ground voltage;
a voltage detection circuit connected between a first voltage source outputting a first voltage and the first resistor; and
a switch element connected between a second voltage source outputting a second voltage and the second resistor, and
wherein the second voltage source includes a battery of the charging circuit or the voltage stabilizing circuit.

20. The power supply system of claim 19, wherein the control part is configured to:
turn off the switch element when the first voltage output from the voltage detection circuit is greater than or equal to a preset reference value; and
turn on the switch element when the first voltage output from the voltage detection circuit is less than the reference value.
